(19) United States
(12) Patent Application Publication
(10) Pub. No.: US 2013/0306984 A1
(43) Pub. Date: Nov. 21, 2013

(54) NORMALLY-OFF-TYPE HETEROJUNCTION FIELD-EFFECT TRANSISTOR

(71) Applicant: John Kevin Twynam, Osaka-shi (JP)

(72) Inventor: John Kevin Twynam, Osaka-shi (JP)

(73) Assignee: SHARP KABUSHIKI KAISHA, Osaka-shi, Osaka (JP)

(21) Appl. No.: 13/984,340

(22) PCT Filed: Jan. 25, 2012
(86) PCT No.: PCT/JP2012/051563

§ 371 Date: Aug. 8, 2013

(30) Foreign Application Priority Data
Mar. 4, 2011 (JP) 2011-047949

(51) Int. Cl. H01L 29/78

(52) U.S. Cl. CPC H01L 29/78
USPC 257/76

(57) ABSTRACT

A normally-off-type HFET includes an undoped AlₓGa₁₋ₓN layer of t₁ thickness; a source electrode and a drain electrode separated from each other and electrically connected to the AlₓGa₁₋ₓN layer; an undoped Al_{y}Ga_{1-y}N layer of t₂ thickness formed between the source electrode and the drain electrode on the AlₓGa₁₋ₓN layer; an undoped Al_{z}Ga_{1-z}N layer of t₃ thickness formed on a partial area of the Al_{y}Ga_{1-y}N layer between the source electrode and the drain electrode; and a Schottky barrier type gate electrode formed on the Al_{z}Ga_{1-z}N layer, wherein conditions of y>x>z and t₁>t₃>t₂ are satisfied.

### TECHNICAL FIELD

The present invention is related to a heterojunction field-effect transistor (HFET) utilizing nitride semiconductors and particularly to improvement of the HFET of a normally-off-type.

### BACKGROUND ART

In comparison with Si-based semiconductors, GaAs-based semiconductors and the like, nitride semiconductors such as GaN and AlGaN have advantages of higher breakdown voltage and excellent heat resistance as well as higher saturated drift velocity of electrons and thus are expected to be able to provide electronic devices that are excellent in high-temperature operation and high-power operation.

In the HFET that is a kind of electronic device formed using such nitride semiconductors, it is well known to generate a two-dimensional electron gas layer due to heterojunction in a nitride semiconductor stacked-layer structure and control electric current between source and drain electrodes by a gate electrode having Schottky barrier junction with the nitride semiconductor layer.

FIG. 11 is a schematic cross-sectional view of a typical conventional HFET using AlGaN/GaN heterojunction. In this HFET, sequentially stacked on a sapphire substrate 501 are a low-temperature GaN buffer layer, undoped GaN layer 503, and an n-type AlGaN layer 504. A source electrode 505 and a drain electrode 506 each including stacked layers of a Ti layer and an Al layer are formed on n-type AlGaN layer 504. A gate electrode 507 including stacked layers of a Ni layer, a Pt layer and an Au layer is formed between source electrode 505 and drain electrode 506. The HFET of FIG. 11 is a normally-on-type in which even when the gate voltage is 0 V, drain current flows due to high density of two-dimensional electron gas generated in a heterointerface between undoped GaN layer 503 and n-type AlGaN layer 504.

When an HFET is used as a power transistor, there are sometimes caused safety flaws, in case of power outage for example, in a circuit including a normally-on-type HFET. Therefore, in order that an HFET is used as a power transistor, it must be a normally-off-type in which current does not flow when its gate voltage is 0 V. To satisfy this requirement, a patent document of Japanese Patent Laying-Open No. 2006-339561 proposes an HFET utilizing a mesa structure and a p-n junction in its gate.

### CITATION LIST

### Patent Document

PTD 1: Japanese Patent Laying-Open No. 2006-339561

### SUMMARY OF INVENTION

### Technical Problem

FIG. 12 shows a schematic cross-sectional view of a normally-off-type HFET disclosed in patent document 1. In this HFET, sequentially stacked on a sapphire substrate 101 are a 100 nm thick MN buffer layer 102, a 2 μM thick undoped GaN layer 103, a 25 nm thick undoped AlGaN layer 104, a 100 nm thick p-type GaN layer 105, and a 5 nm thick heavily-doped p-type layer 106. Undoped AlGaN layer 104 in this HFET is formed with undoped Al_{0.25}Ga_{0.75}N, and formed thereon are p-type GaN layer 105 and heavily doped p-type GaN layer 106 that compose a mesa.

Provided on heavily doped p-type GaN layer 106 is a Pd gate electrode 111 in ohmic contact therewith. Further, provided on undoped AlGaN layer 104 are a source electrode 109 and a drain electrode 110 each including stacked layer of a Ti layer and an Al layer, between which p-type GaN layer 105 is positioned. These electrodes are provided in an area surrounded by a device isolation region 107. Furthermore, the upper surface of the nitride semiconductor stacked-layer structure is protected with a SiN film 108.

The important feature in the HFET of FIG. 12 resides in that since gate electrode 111 forms ohmic contact with heavily doped p-type GaN layer, p-n junction is formed between p-type GaN layer 105 and a two-dimensional electron gas layer formed in the interface between undoped AlGaN layer 104 and undoped GaN layer 103 in the gate region. Then, since the barrier due to p-n junction is higher than the barrier due to Schottky barrier junction, gate current leak hardly occurs even with high gate voltage in this HFET as compared to a conventional HFET including a gate electrode having Schottky barrier junction.

Further, in the HFET of FIG. 12, heavily doped p-type GaN layer 106 is provided beneath gate electrode 111, and thus ohmic junction is readily formed with gate electrode 111. In general it is difficult to form ohmic contact with a p-type nitride semiconductor, and therefore heavily doped p-type GaN layer 106 is provided.

In the meantime, it is well known that it is not easy to generate p-type carriers at high density by activating p-type impurities of high density. In general, in order to generate p-type carriers at high density by activating p-type impurities of high density, electron irradiation or high-temperature annealing is required.

Therefore, an object of the present invention is to provide a normally-off-type HFET with an easier process and a lower cost, without the necessity of doping of p-type impurities and activation of the p-type impurities.

### Solution to Problem

A normally-off-type HFET according to the present invention includes: an undoped AlₓGa₁₋ₓN layer of t₁ thickness; a source electrode and a drain electrode separated from each other and electrically connected to the AlₓGa₁₋ₓN layer; an undoped Al_{y}Ga_{1-y}N layer of t₂ thickness formed between the source electrode and the drain electrode on the AlₓGa₁₋ₓN layer; an undoped Al_{z}Ga_{1-z}N layer of t₃ thickness formed in a shape of a mesa on a partial area of the Al_{y}Ga_{1-y}N layer between the source electrode and the drain electrode; and a Schottky barrier type gate electrode formed on the Al_{z}Ga_{1-z}N layer, wherein conditions of y>x>z and t₁>t₃>t₂ are satisfied.

Incidentally, it is preferable that a condition of x−z>0.03 is satisfied. It is also preferable that a condition of t₃/t₂>4 is satisfied. The gate electrode can be formed with a Ni/Au stacked layer, a WN layer, a TiN layer, a W layer, or a Ti layer. It is further preferable that an undoped GaN layer of a thickness of 10 nm or more and less than 50 nm is inserted between the AlₓGa₁₋ₓN layer and the Al_{y}Ga_{1-y}N layer. It is still further desirable that the AlₓGa₁₋ₓN layer, the Al_{y}Ga_{1-y}N layer and the Al_{z}Ga_{1-z}N layer have a Ga polarity in which Ga atoms appear on a (0001) surface of the upper surface side.

### Advantageous Effects of Invention

According to the invention as above, it is possible to provide a normally-off-type HFET with an easier process and a lower cost, without the necessity of doping of p-type impurities and activation of the p-type impurities.

### BRIEF DESCRIPTION OF DRAWINGS

FIG. 1 is a schematic cross-sectional view of an HFET according to an embodiment of the present invention.

FIG. 2 is a graph schematically showing an example of energy band structure in the HFET of FIG. 1.

FIG. 3 is a graph showing the relation between the sheet charge density qnₛ and the source-gate voltage V_{gs} in the HFET of FIG. 1.

FIG. 4 is a graph schematically showing, in the energy band structure, the fixed sheet charge density σ caused by the polarity difference between two adjacent layers in the vicinity of the heterojunction interface.

FIG. 5 is a graph showing a result of calculation determining the relation between the threshold voltage Vₜₕ and the Al composition ratio in the plurality of nitride semiconductor layers included in the HFET of FIG. 1.

FIG. 6 is a graph showing a result of calculation determining the relation between the threshold voltage Vₜₕ and the thickness ratio in the plurality of nitride semiconductor layers included in the HFET of FIG. 1.

FIG. 7 is a graph showing measured data of the relation between the drain current I_{d} and the source-gate voltage V_{gs} in the HFET of FIG. 1.

FIG. 8 is a graph showing measured data of the relation between the drain current I_{d} and the source-drain voltage V_{ds} in the HFET of FIG. 1.

FIG. 9 is a schematic cross-sectional view of an HFET according to another embodiment of the present invention.

FIG. 10 is a graph schematically showing an example of energy band structure in the HFET of FIG. 9.

FIG. 11 is a schematic cross-sectional view of a conventional normally-on-type HFET.

FIG. 12 is a schematic cross-sectional view of a normally-off-type HFET according to patent document 1.

### DESCRIPTION OF EMBODIMENTS

FIG. 1 is a schematic cross-sectional view of an HFET according to an embodiment of the present invention. Incidentally, the thickness, length, width, etc. in the drawings of this application are arbitrarily changed for clarity and simplicity of the drawings and thus do not reflect their actual dimensional relation.

In an HFET of FIG. 1, an AlₓGa₁₋ₓN layer 11 of t₁ thickness is stacked on a substrate such as of sapphire (not shown) with a buffer layer 10 intervening therebetween. A source electrode 21 and a drain electrode 22 are formed separated from each other so as to be electrically connected to AlₓGa₁₋ₓN layer 11. An undoped Al_{y}Ga_{1-y}N layer 12 of t₂ thickness is deposited between source electrode 21 and drain electrode 22 on AlₓGa₁₋ₓN layer 11. An undoped Al_{z}Ga₁₋ₓN layer 13 of t₃ thickness is formed in a shape of a mesa on a partial area of Al_{y}Ga_{1-y}N layer 12 between source electrode 21 and drain electrode 22. A gate electrode 23 of a Schottky barrier type is formed on Al_{z}Ga_{1-z}N layer 13. Incidentally, each of these AlₓGa₁₋ₓN layer, Al_{y}Ga_{1-y}N layer and Al_{z}Ga_{1-z}N layer has a Ga polarity in which Ga atoms appear on a (0001) surface of the upper surface side.

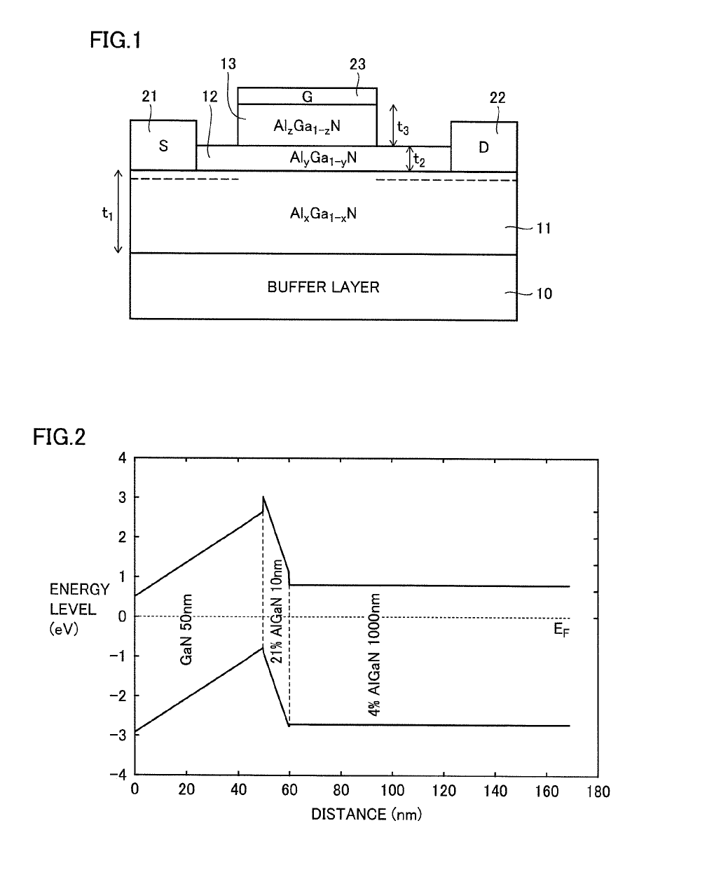

A graph of FIG. 2 schematically shows an example of energy band structure in the HFET of FIG. 1. Namely, the horizontal axis of this graph represents the distance (nm) in the depth direction from the upper surface of Al_{z}Ga_{1-z}N layer 13, while the vertical axis represents the electron energy level (eV) with the Fermi energy level E_{F} being a reference level of 0 eV. In the example of FIG. 2, there are set x=0.04, t₁=1000 nm, y=0.21, t₂=10 nm, z=0, and t₃=50 nm.

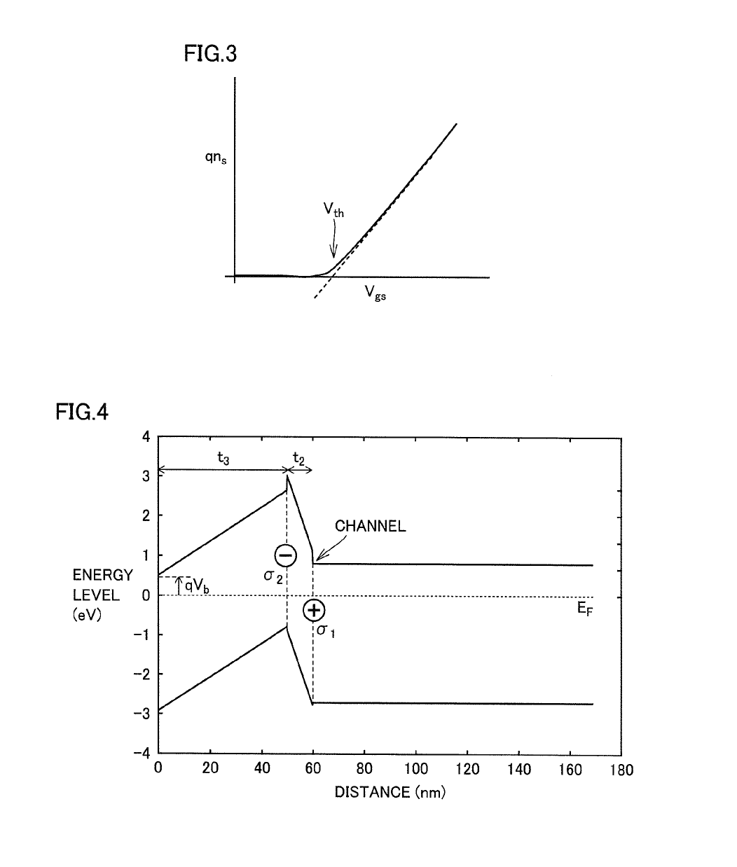

FIG. 3 is a graph showing the relation between the sheet charge density qnₛ and the source-gate voltage V_{gs} in the HFET. As shown with a solid curved line in this graph, the threshold voltage Vₜₕ corresponds to the source-gate voltage V_{gs} when the sheet charge density qnₛ shifts to the positive value side with the increased V_{gs}.

The positive value part of the solid curved line in the graph of FIG. 3 can be approximated with a linear line shown by a broken line, and the sheet charge density qnₛ (C/cm²) can be expressed with the following formula (1) proportional to V_{gs}. Incidentally, this formula (1) can be derived from a capacitance model.

qnₛ=σ₁+σ₂·t₃∈₂/(t₂∈₃+t₃∈₂)+C·(V_{gs}−V_{b}) (1)

Here, q denotes the charge of an electron, nₛ denotes the sheet electron density (cm⁻²), σ₁ denotes the positive fixed sheet charge density due to polarization difference between AlₓGa₁₋ₓN layer 11 and Al_{y}Ga_{1-y}N layer 12, σ₂ denotes the negative fixed sheet charge density due to polarization difference between Al_{y}Ga_{1-y}N layer 12 and Al_{z}Ga_{1-z}N layer 13, t₂ and t₃ respectively denote the thicknesses of Al_{y}Ga_{1-y}N layer 12 and Al_{z}Ga_{1-z}N layer 13, ∈₂ and ∈₃ respectively denote the dielectric constants of Al_{y}Ga_{1-y}N layer 12 and Al_{z}Ga_{1-z}N layer 13, C denotes the capacitance per unit area between the channel layer and the gate electrode (also called as gate capacitance), V_{gs} denotes the gate-source voltage, and V_{b} denotes (1/q)·(Shottky barrier height of the gate electrode).

As a reference to formula (1), FIG. 4 schematically shows the fixed sheet charge densities σ₁ and σ₂ in the energy band structure corresponding to FIG. 2.

In the case of the normally-off-type of HFET, since qnₛ=0/cm² should be established when V_{gs}=Vₜₕ (threshold voltage), formula (2) is derived from formula (1) and can be changed into formula (3).

0=σ₁+σ₂·t₃∈₂/(t₂∈₃+t₃∈₂)+C·(Vₜₕ−V_{b}) (2)

Vₜₕ=V_{b}−(1/C)·{σ₁+σ₂·t₃∈₂/(t₂∈₃+t₃∈₂)} (3)

Further, since 1/C=t₂/∈₂+t₃/∈₃, formula (3) can be changed into formula (4).

Vₜₕ=V_{b}−(t₂/∈₂+t₃/∈₃)·{σ₁+σ₂·t₃∈₂/(t₂∈₃+t₃∈₂)} (4)

Here, ∈₂≈∈₃ can be presumed and thus formula (4) can be changed into formula (5).

Vₜₕ≈V_{b}−σ₁(t₂+t₃)/∈₃−σ₂·t₃/∈₃ (5)

Further, σ₁ depends on the Al composition ratios in AlₓGa₁₋ₓN layer 11 and Al_{y}Ga_{1-y}N layer 12, and it can be expressed with σ₁=a(y−x). Similarly, σ₂ depends on the Al composition ratios in Al_{y}Ga_{1-y}N layer 12 and Al_{z}Ga_{1-z}N layer 13, and it can be expressed with σ₂=a(z−y). Here, “a” denotes a proportional constant (C/cm²).

Therefore, formula (5) can be changed into formula (6) and then into formula (7).

Vₜₕ≈V_{b}−a(Y−x)(t₂+t₃)/∈₃−a(z−y)t₃/∈₃ (6)

Vₜₕ≈V_{b}+a(x−z)t₃/∈₃−a(y−z)t₂/∈₃ (7)

Here, the proportional constant “a” can be determined experimentally and it is possible to adopt a value of a=8.65×10⁻⁶C/cm².

A graph of FIG. 5 shows the threshold voltage Vₜₕ obtained depending on (x−z) under the condition that t₂=10 nm, t₃=50 nm, y−x=0.17, and V_{b}=1.0V are presumed as typical values in formula (7). Namely, the horizontal axis of the FIG. 5 graph represents the (x−z) and the vertical axis represents the Vₜₕ (V). As seen in the graph of FIG. 5, it is preferable to satisfy a condition of x−z>0.03 in order to obtain a normally-off-type HFET having a threshold voltage Vₜₕ>1 higher than Vₜₕ=0V. It is also understood that the Vₜₕ can be made higher by increasing the value of “x”.

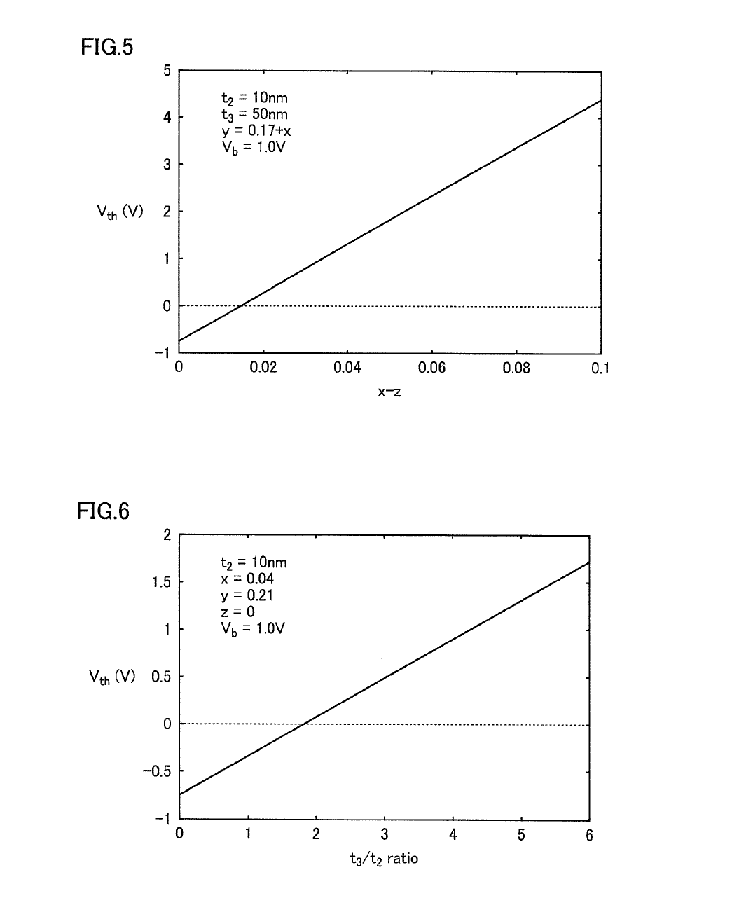

A graph of FIG. 6 shows the threshold voltage Vₜₕ obtained depending on t₃/t₂ under the condition that x=0.04, y=0.21, z=0, t₂=10 nm, and V_{b}=1.0V are presumed as typical values in formula (7). Namely, the horizontal axis of the FIG. 6 graph represents the t₃/t₂ and the vertical axis represents the Vₜₕ (V). As seen in the graph of FIG. 6, it is preferable to satisfy a condition of t₃/t₂>4 in order to obtain a normally-off-type HFET having a threshold voltage Vₜₕ>1 higher than Vₜₕ=0V.

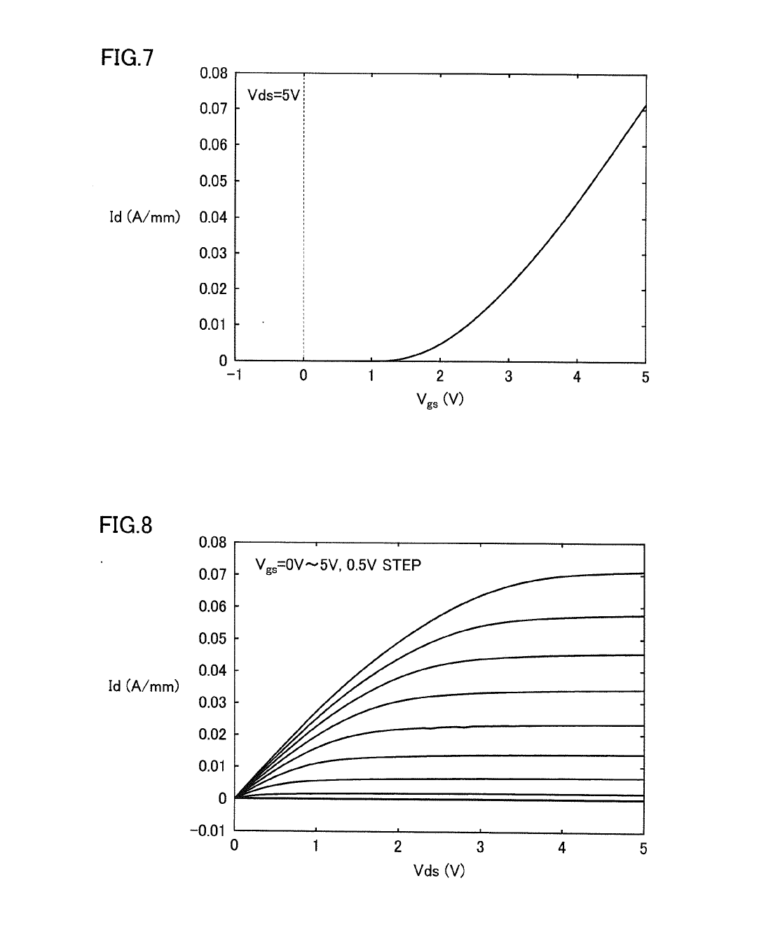

Graphs of FIG. 7 and FIG. 8 show measured voltage-current characteristics in the HFET of FIG. 1 in the case that x=0.04, y=0.21, t₂=10 nm, z=0, and t₃=50 nm are set, and source electrode 21 and drain electrode 22 are formed with a TiAl layer while gate electrode 23 is formed with a TiN layer.

The horizontal axis of the FIG. 7 graph represents the source-gate voltage V_{gs} (V), and the vertical axis represents the drain current I_{d} (A/mm). Here, it should be noted that the source-drain voltage V_{ds} is set to 5V. In the graph of FIG. 7, it is seen that the I_{d} rises after the V_{gs} becomes greater than 1V, and therefore it is understood that the threshold voltage Vₜₕ is actually greater than 1V.

The horizontal axis of the FIG. 8 graph represents the source-drain voltage V_{ds} (V), and the vertical axis represents the drain current I_{d} (A/mm). Here, it should be noted that the curved lines shown in this graph correspond to the condition that the source-gate voltage V_{gs} was sequentially increased from 0V to 5V by a 0.5V step between a lower line and the next upper line.

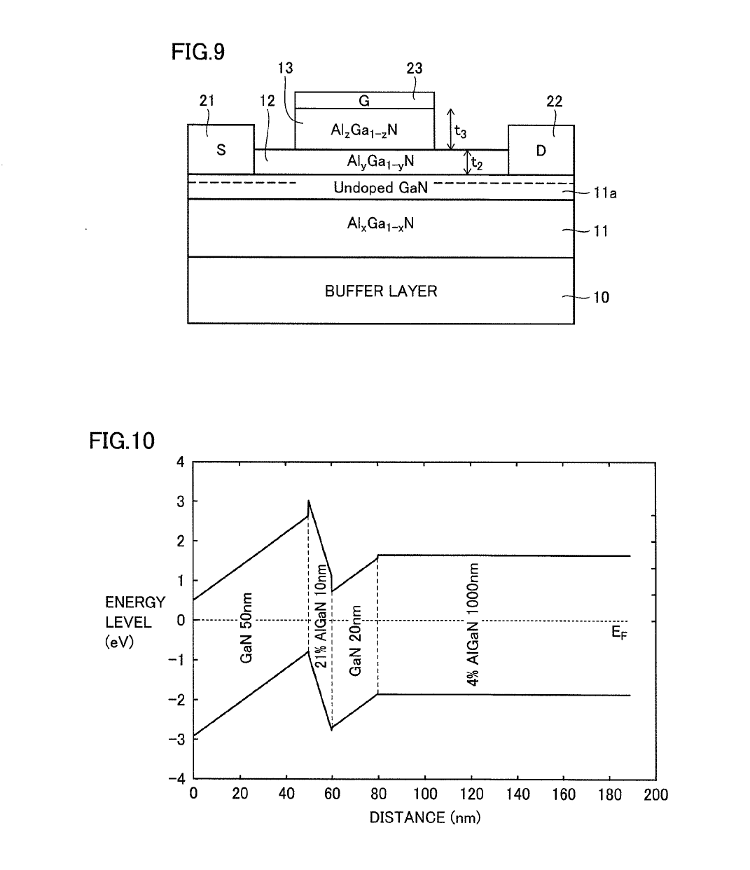

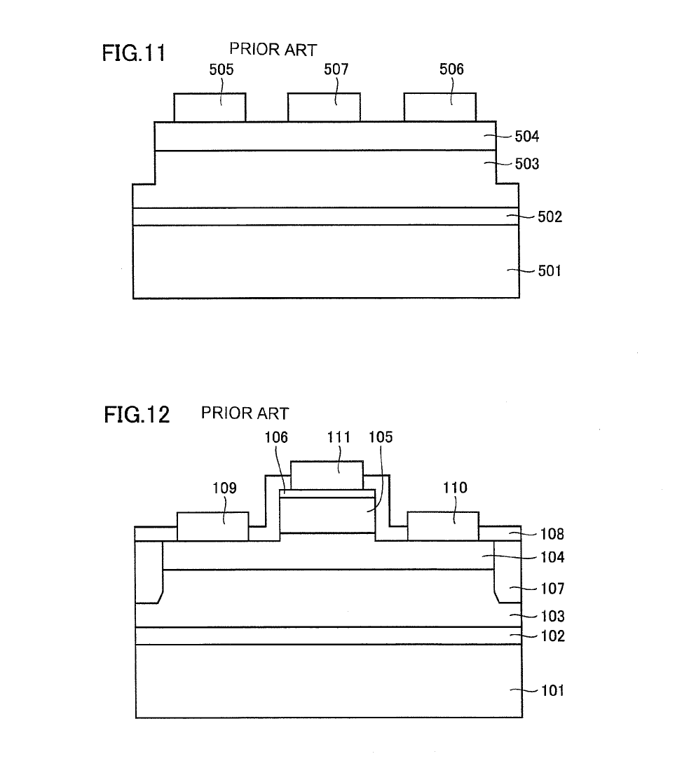

FIG. 9 is a schematic cross-sectional view of an HFET according to another embodiment of the present invention. As compared to FIG. 1, the FIG. 9 HFET is different only in that a GaN layer 11a of a thickness in a range of 10 nm to 50 nm is inserted between AlₓGa₁₋ₓN layer 11 and undoped Al_{y}Ga_{1-y}N layer 12. This GaN layer 11a does not contain Al atoms different from Ga atoms and thus is preferable as a channel layer in view of less electron scattering caused by the different atoms and then higher electron mobility therein.

A graph of FIG. 10 similar to FIG. 2 schematically shows an energy band structure in the FIG. 9 HFET including GaN layer 11a of 20 nm thickness.

### INDUSTRIAL APPLICABILITY

As described above, according to the present invention, it is possible to provide a normally-off-type HFET with an easier process and a lower cost, without the necessity of doping of p-type impurities and activation of the p-type impurities.

### REFERENCE SIGNS LIST

10: buffer layer; 11: undoped AlₓGa₁₋ₓN layer; 11a: undoped GaN layer; 12: undoped Al_{y}Ga_{1-y}N layer; 13: undoped Al_{z}Ga_{1-z}N layer; 21: source electrode; 22 drain electrode; and 23: Schottky barrier type gate electrode.

1. A normally-off-type HFET comprising:
an undoped AlₓGa₁₋ₓN layer of t₁ thickness;
a source electrode and a drain electrode separated from each other and electrically connected to the AlₓGa₁₋ₓN layer;
an undoped Al_{y}Ga_{1-y}N layer of t₂ thickness formed between the source electrode and the drain electrode on the AlₓGa₁₋ₓN layer;
an undoped Al_{z}Ga_{1-z}N layer of t₃ thickness formed in a shape of a mesa on a partial area of the Al_{y}Ga_{1-y}N layer between the source electrode and the drain electrode; and
a Schottky barrier type gate electrode formed on the Al_{z}Ga_{1-z}N layer,
wherein conditions of y>x>z and t₁>t₃>t₂ are satisfied.

2. The normally-off-type HFET according to claim 1, wherein a condition of x−z>0.03 is satisfied.

3. The normally-off-type HFET according to claim 1, wherein a condition of t₃/t₂>4 is satisfied.

4. The normally-off-type HFET according to claim 1, wherein gate electrode comprises a Ni/Au stacked layer, a WN layer, a TiN layer, a W layer, or a Ti layer.

5. The normally-off-type HFET according to claim 1, further comprising an undoped GaN layer of a thickness of 10 nm or more and less than 50 nm between the AlₓGa₁₋ₓN layer and the Al_{y}Ga_{1-y}N layer.

6. The normally-off-type HFET according to claim 1, wherein the AlₓGa₁₋ₓN layer, the Al_{y}Ga_{1-y}N layer and the Al_{z}Ga_{1-z}N layer have a Ga polarity in which Ga atoms appear on a surface of the upper surface side.
